(19) United States
(12) Patent Application Publication
(10) Pub. No.: US 2009/0303825 A1
(43) Pub. Date: Dec. 10, 2009

(54) SEMICONDUCTOR MEMORY DEVICE

(75) Inventors: Dong-Keun KIM, Gyeonggi-do (KR); Jee-Eun Lee, Gyeonggi-do (KR)

Correspondence Address: IP & T Law Firm PLC, 7700 Little River Turnpike, Suite 207, Fairfax, VA, 22003, US

(73) Assignee: HYNIX SEMICONDUCTOR, INC., Gyeonggi-do (KR)

(21) Appl. No.: 12/347,547

(22) Filed: Dec. 31, 2008

(30) Foreign Application Priority Data
Jun. 4, 2008 (KR) 10-2008-0052770

(51) Int. Cl. G11C 8/00; G11C 8/08

(52) U.S. Cl. 365/230.03; 365/230.06

(57) ABSTRACT

A semiconductor memory device includes a first plurality of banks arranged in a first direction to form a first group of banks; a second plurality of banks arranged in the first direction to form a second group of banks, the first group of banks and the second group of banks arranged in a second direction; a first local data line arranged in the second direction to cross a bank of the second plurality of banks and to transfer input/output data; a second local data line arranged in the second direction to transfer input/output data; a global data line disposed in the first direction that crosses the second direction; and a data exchanger disposed between the second plurality of banks and the global data line for configured to controlling data exchange between the first and second local data lines and the global data line.

### CROSS-REFERENCE TO RELATED APPLICATION

The present invention claims priority of Korean patent application number 10-2008-0052770, filed on Jun. 4, 2008, which is incorporated by reference in its entirety.

### BACKGROUND OF THE INVENTION

The present invention relates to semiconductor design technology, and more particularly, to a semiconductor memory device that stably transfers data at a high speed and has a relatively small circuit area by effectively arranging data input/output lines connected to a plurality of stacked banks.

In general, a semiconductor memory device such as a double data rate synchronous DRAM (DDR SDRAM) includes a plurality of banks, and each of the banks includes a plurality of memory cells in order to store data and output stored data.

Lately, semiconductor memory devices have been designed to include more banks in order to satisfy a demand of high capacity. Therefore, there were many efforts made to maximize the operation characteristics of the semiconductor memory device by effectively arranging banks. In order to effectively arrange the banks, a semiconductor memory device has been designed as follows. A plurality of banks are divided into an up-bank group and a down-bank group, and the plurality of banks are arranged as a stack structure.

FIG. 1 is a block diagram illustrating arrangement of regions in a semiconductor memory device according to the related art.

Referring to FIG. 1, the semiconductor memory device includes an up-bank region 110, a down-bank region 130, and a peripheral region150.

The up-band region 110 and the down-bank region 130 include a plurality of banks, a plurality of column decoders and row decoders corresponding to the plurality of banks, and a plurality of write drivers and read drivers as data exchange circuits. The peripheral region 150 includes a plurality of pads.

FIG. 2 is a block diagram illustrating an up-bank region 110 and a peripheral region 150 of FIG. 1. For convenience, detail description of the down-bank region 130 is omitted because the down-bank region 130 has a structure similar to that of the up-bank region 110.

Referring to FIG. 2, the up-bank region 110 includes first to eighth banks 210_1 to 210_8, first to fourth row decoders 230_12, 230_34, 230_56, and 230_78, first to eighth column decoders 250_1 to 250_8, first to eighth write drivers 270_1, to 270_8, and first to eighth read drivers 290_1 to 290_8. The peripheral region 150 includes first to eighth pads DQ1 to DQ8.

Each of the first to eighth banks 210_1 to 210_8 includes a plurality of memory cells for storing data. That is, each of the first to eighth banks stores data at corresponding memory cells in a write operation of the semiconductor memory device and outputs data stored in a corresponding memory cell in a read operation of the semiconductor memory device.

Each of the first to fourth row decoders 230_12, 230_34, 230_56, and 230_78 selects a corresponding word line (not shown) by decoding a row address inputted from an external device. Each of the first to eighth column decoders 250_1 to 250_8 activates a corresponding one of first to eighth column selection signals YI1 to YI8 by decoding a column address inputted from an external device.

Each of the first to eighth write drivers 270_1 to 270_8 transfers data, which is applied from an external device, from a corresponding global input/output line to a corresponding local input/output line in a write operation of a semiconductor memory device. One or more of the first to eighth write drivers 270_1 to 270_8 are included in each bank.

Each of the first to eighth read drivers 290_1 to 290_8 transfers data stored in a corresponding bank from a corresponding local input/output line to a corresponding global input/output line in a read operation of a semiconductor memory device. One or more of the first to eighth read drivers 290_1 to 290_8 is included in a corresponding bank.

The first to eighth banks 210_1 to 210_8 are stacked in a vertical direction, that is, a column direction. For example, the first bank 210_1 and the third bank 210_3 are stacked, and the second bank 210_2 and the fourth bank 210_4 are stacked. Also, the fifth bank 210_5 and the seventh bank 210_7 are stacked, and the sixth bank 210_6 and the eighth bank 210_8 are stacked.

Hereinafter, input/output lines connecting each of constituent elements will be described.

The first to eighth banks 210_1 to 210_8 are respectively connected to the first to eighth writer drivers 270_1 to 270_8, and the first to eighth read drivers 290_1 to 290_8 through a plurality of first to eighth local input/output lines LIO1 to LIO8. Each of the local input/output lines transfers data between a bank and corresponding write drivers or between a bank and corresponding read drivers. Here, each of the first to eighth local input/output lines LIO1 to LIO8 includes a positive local input/output line and a negative local input/output line. For convenience, the positive local input/output line and the negative local input/output line are shown as one local input/output line.

The first to eighth write drivers 270_1 to 270_8 and the first to eighth read drivers 290_1 to 290_8 are connected to global input/output lines GIO1, GIO2, and GIO3 corresponding to the first to eighth pads DQ1 to DQ8.

For convenience, the global input/output lines are classified into a first global input/output line GIO1, a second global input/output line GIO2, and a third global input/output line GIO3. The first to third global input/output lines GIO1 to GIO3 transfer data to corresponding banks. That is, the first global input/output line GIO1 transfers data corresponding to the first and second banks 210_1 and 210_2 and the fifth and sixth banks 210_5 and 210_6. The second global input/output line GIO2 transfers data corresponding to the third and fourth 210_3 and 210_4 and the seventh and eighth banks 210_7 and 210_8. The third global input/output line GIO3 transfers data of the first and second global input/output lines GIO1 and GIO2.

FIG. 3 is a diagram describing a read operation and a write operation according to the related art. FIG. 3 illustrates one of memory cells that form the first to eighth banks 210_1 to 210_8 representatively. For convenience, a reference numeral 310 is assigned to the memory cell.

Hereinafter, a read operation will be described with reference to FIG. 3.

In a read operation, a word line (WL) is selected by decoding a row address. The selected word line is activated. Then, a cell transistor T1 of a memory cell 310 is turned on, and data stored in a cell capacitor C1 is charge-shared at pre-charged positive/negative bit lines BL and /BL. The positive bit line BL and the negative bit line /BL have a small electric potential difference through the charge sharing operation. A pre-charged voltage level has a ½ voltage level of a core voltage which is an internal voltage.

Then, a bit line sense amplifier 320 senses and amplifies a small electric potential of a positive bit line BL and a corresponding negative bit line /BL. If the electric potential of the positive bit line BL is higher than that of the negative bit line /BL, a voltage of the positive bit line BL is amplified to a pull-up supply voltage RTO and a voltage of the negative bit line /BL is amplified to a pull-down supply voltage SB. On the contrary, if the electric potential of the positive bit line BL is lower than the electric potential of the negative bit line /BL, the bit line sense amplifier 320 senses and amplifies the voltage of the positive bit line BL to a pull-down supply voltage SB and amplifies the voltage of the negative bit line /BL to a pull-up supply voltage RTO.

Meanwhile, if a column selector 330 is activated in response to a column selection signal YI selected by decoding the column address, the positive/negative bit lines BL and /BL are positive/negative segment input/output lines SIO and /SIO are connected. That is, data amplified at the positive bit line BL is transferred to the positive segment input/output line SIO, and data amplified at the negative bit line /BL is transferred to the negative segment input/output line /SIO. Then, if an input/output switch 340 is activated in response to an input/output control signal CTR_IO, the positive/negative segment input/output lines SIO and /SIO and the positive/negative local input/output lines LIO and /LIO are connected together. That is, data transferred to the positive segment input/output line SIO is transferred to the positive local input/output line LIO, and data transferred to the negative segment input/output line /SIO is transferred to the negative local input/output line /LIO. The read driver 350 drives a global input/output line GIO according to the transferred data through the positive/negative local input/output lines LIO and /LIO.

Finally, data stored in the memory cell 310 is transferred from the positive/negative bit lines BL and /BL to the positive/negative segment input/output lines SIO and /SIO, from the positive/negative segment input/output lines SIO and /SIO to the positive/negative local input/output lines LIO and /LIO, and from the positive/negative local input/output lines LIO and /LIO to the global input/output line GIO. Such transferred data is outputted to an external device through a corresponding pad (see FIG. 2).

Meanwhile, data applied from an external device in a write operation is transferred in an opposition direction of the read operation. That is, data applied through a pad is transferred from the global input/output line GIO to the positive/negative local input/output lines LIO and /LIO through the write driver 360, from the positive/negative local input/output lines LIO and /LIO to the positive/negative segment input/output lines SIO and /SIO, and from the positive/negative segment input/output lines SIO and /SIO to the positive/negative bit lines BL and /BL. Such transferred data is finally stored in the cell memory 310.

As a reference, data transferred through each of the lines is reflected to RC loading by a plurality of resistances R and capacitors C shown in FIG. 3.

Meanwhile, further more numbers of banks are disposed in a stack structure in a semiconductor memory device to increase the capacity thereof. As the number of banks increases, the number of global input/output lines also increases. Therefore, the length thereof extends too. The length of the global input/output line has close relation with a data transfer rate. As much as an extended length of the global input/output line, the data transfer rate decreases.

Referring to FIG. 2 again, the first global input/output line GIO1 transfers data corresponding to the first and second bank 210_1 and 210_2 and the fifth and sixth banks 210_5 and 210_6 to the third global input/output line GIO3. The second global input/output line GIO2 transfers data corresponding to the third and fourth banks 210_3 and 210_4 and the seventh and eighth bank 210_7 and 210_8 to the third global input/output line GIO3 in the stacked bank structure. In a view of semiconductor memory device, the first to third global input/output lines GIO1, GIO2, and GIO3 are very long, occupy a large area, and have great load, accordingly. If the number of banks increases, loading thereof also increases as much as the increment of the number of banks. Therefore, the data transfer rate disadvantageously decreases.

If the number of the global input/output lines increases in the stacked bank structure, the area occupied by the global input/output line increases too. It causes a problem of increasing an overall circuit in size. The large size of the overall circuit may cause the decrement of productivity and the increment of a manufacturing cost.

Also, large loading difference is generated between the first global input/output line GIO1 and the second global input/output line GIO2. Accordingly, a time of transmitting data may be changed disadvantageously. In other word, a data transfer rate of data transmitted through the first global input/output line GIO1 may be different from a data transfer rate of data transmitted through the second global input/output line GIO2. That is, a time for transferring data of the first bank 210_1 from the first global input/output line GIO1 to the third global input/output line GIO3 and outputting to the first pad DQ1 is different from a time for transferring data of the third bank 210_3 from the second global input/output line GIO2 to the third global input/output line GIO3 and outputting to the first pad DQ1. In this case, it is impossible to regularly receive data from an external device, thereby deteriorating the reliability of the semiconductor memory device.

### SUMMARY OF THE INVENTION

Embodiments of the present invention are directed to providing a semiconductor memory device for optimizing a data transfer rate of each of stacked banks.

Embodiments of the present invention are also directed to providing a semiconductor memory device for reducing a size thereof by minimizing an area and a length of a global input/output line.

In accordance with an aspect of the present invention, there is provided a semiconductor memory device including a first plurality of banks arranged in a first direction to form a first group of banks; a second plurality of banks arranged in the first direction to form a second group of banks, the first group of banks and the second group of banks arranged in a second direction; a first local data line arranged in the second direction to cross a bank of the second plurality of banks and to transfer input/output data to a bank of the first plurality of banks; a second local data line arranged in the second direction to transfer input/output data to the bank of the second plurality of banks; a global data line disposed in the first direction that crosses the second direction; and a data exchanger disposed between the second plurality of banks and the global data line configured to control data exchange between the first and second local data lines and the global data line.

In accordance with another aspect of the present invention, there is provided a semiconductor memory device including a first plurality of banks arranged in a first direction to form a first up-bank array; a second plurality of banks arranged in the first direction to form a second up-bank array, the first up-bank array and the second up-bank array arranged in a second direction that crosses the first direction; a plurality of first local data lines arranged to cross the second up-bank array for transferring input/output data to/from the first up-bank array; a plurality of second local data lines configured to transfer input/output data to/from the second up-bank array; a plurality of data exchangers configured to control data exchange between the plurality of first local data lines and the plurality of second local data lines, and the global data line, and disposed between the global data line arranged in the second direction and the plurality of banks; and a plurality of pads coupled to the global data line and disposed to interface with the data exchangers based on data on the global data line.

In accordance with another aspect of the present invention, there is provided a semiconductor memory device including up and down bank groups having a first bank array disposed in a second direction that crosses a first direction and corresponding to the second direction and a second bank array stacked with the first bank array and arranged in the first direction, a plurality of up data exchangers disposed between an up global data line disposed in the second direction and the up bank group for exchanging data between a plurality of local data lines corresponding to the up bank group and the up global data line, a plurality of down data exchangers disposed between a down global data line disposed in the second direction and the down bank group for exchanging data between a plurality of local data lines corresponding to the down bank group and the down global data line, a plurality of up pads coupled to the up global data line and disposed to interface with the up data exchangers based on data on the up global data line, and a plurality of down pads coupled to the down global data line and disposed to interface with the down data exchangers based on the down global data line. Each of the up and down bank groups includes a plurality of first local data lines for transferring input/output data to a bank included in the first bank array and disposed to cross the second bank array, and a plurality of second local data lines for transferring input/output data to a bank included in the second bank array.

In accordance with another aspect of the present invention, there is provided a semiconductor memory device including up and down bank groups having a first bank array disposed in a second direction that crosses a first direction and corresponding to the second direction and a second bank array stacked with the first bank array and arranged in the first direction, a plurality of up data exchangers disposed between a global data line arranged in the second direction and the up bank group for exchanging data between a plurality of local data lines corresponding to the up bank group and the global data line, a plurality of down exchangers disposed between the global data line and the down bank group for exchanging data between a plurality of local data lines corresponding to the down bank group and the global data line, a plurality of up pads coupled to the global data line and disposed between the global data line and the up data exchangers, and a plurality of down pads coupled to the global data line and disposed between the global data line and the down data exchangers. Each of the up and down bank groups includes a plurality of first local data lines disposed to cross the second bank array for transferring input/output data to a bank included in the first bank array and a plurality of second local data lines for transferring input/output data to a bank included in the second bank array.

Lately, a semiconductor includes more banks due to a trend of a large capacity. Accordingly, the number of global input/output lines increases and the length of the global input/output line also extends corresponding to the number of banks in the semiconductor memory device. The long global input/output lines reduce a data transmission speed in the semiconductor device and increase the size of the semiconductor device. Also, a data transmission speed of a first global input/output line GIO1 may become different from that of a second global input/output line GIO2, thereby degrading the reliability of the semiconductor memory device. In the present invention, an area occupied by the global input/output line and the length of the global input/output line are minimized by disposing a data exchanger at one side of stacked banks.

### BRIEF DESCRIPTION OF THE DRAWINGS

FIG. 1 is a block diagram illustrating arrangement of regions in a semiconductor memory device according to the related art.

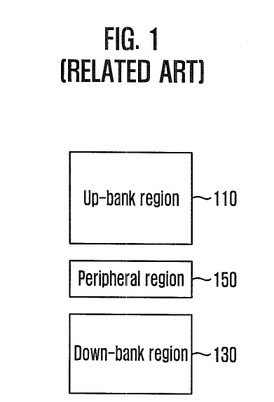

FIG. 2 is a block diagram illustrating an up-bank region 110 and a peripheral region 150 of FIG. 1.

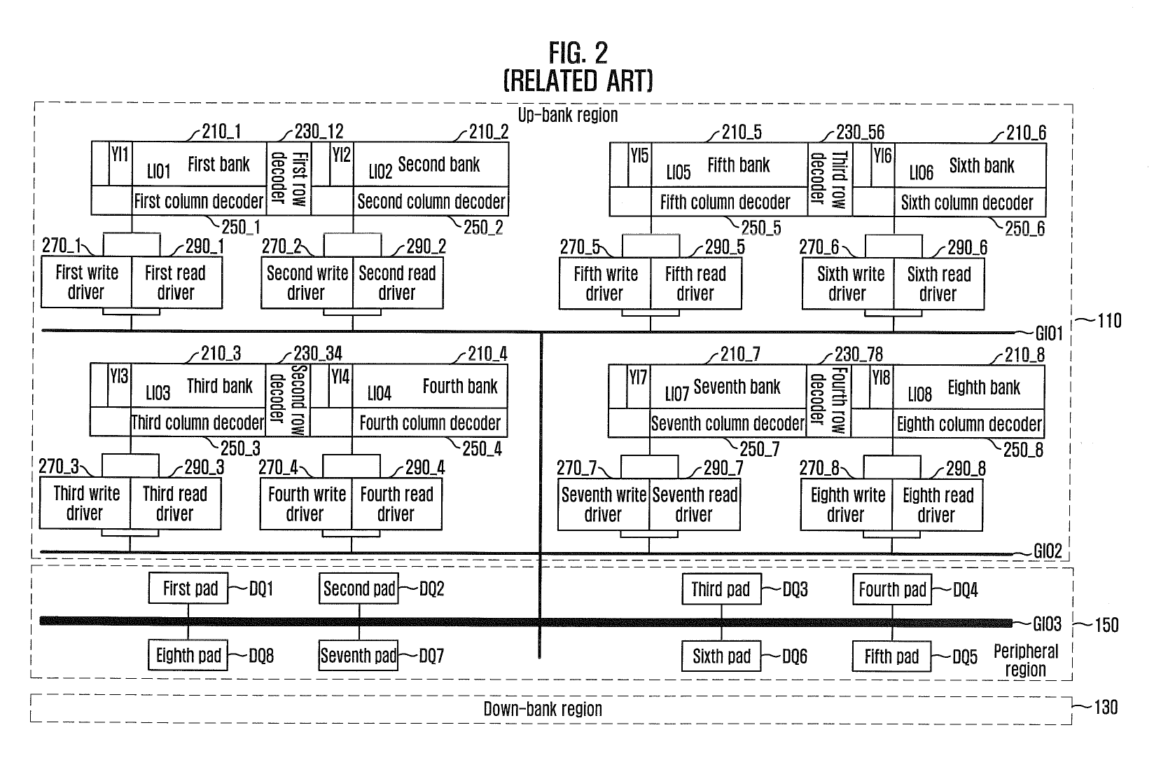

FIG. 3 is a diagram describing a read operation and a write operation according to the related art.

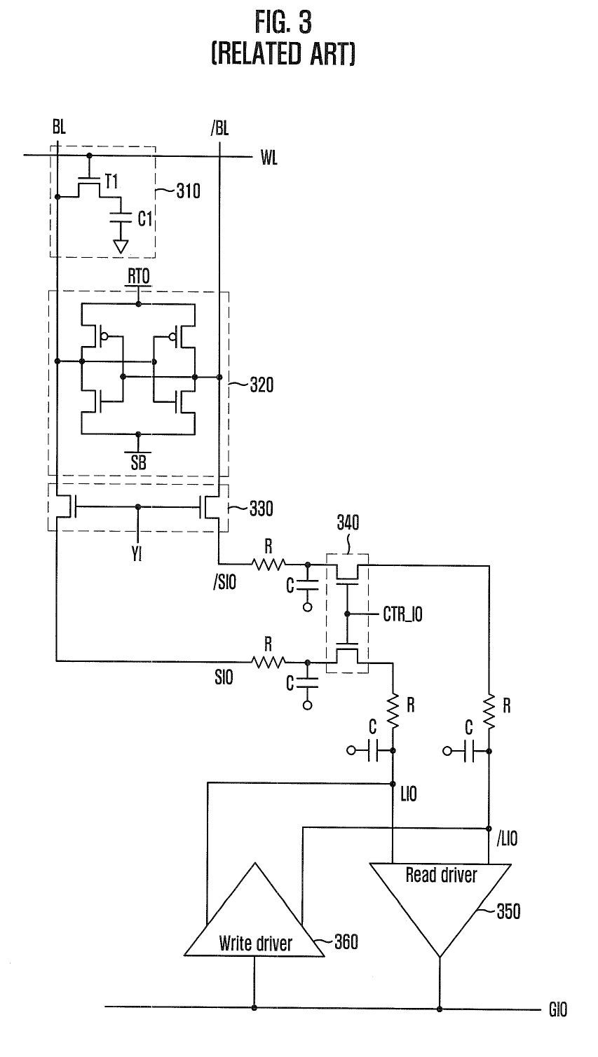

FIG. 4 is a block diagram illustrating a part of a semiconductor memory device in accordance with an embodiment of the present invention

FIG. 5 is a block diagram illustrating a semiconductor memory device in accordance with another embodiment of the present invention.

### DESCRIPTION OF SPECIFIC EMBODIMENTS

Other objects and advantages of the present invention can be understood by the following description, and become apparent with reference to the embodiments of the present invention.

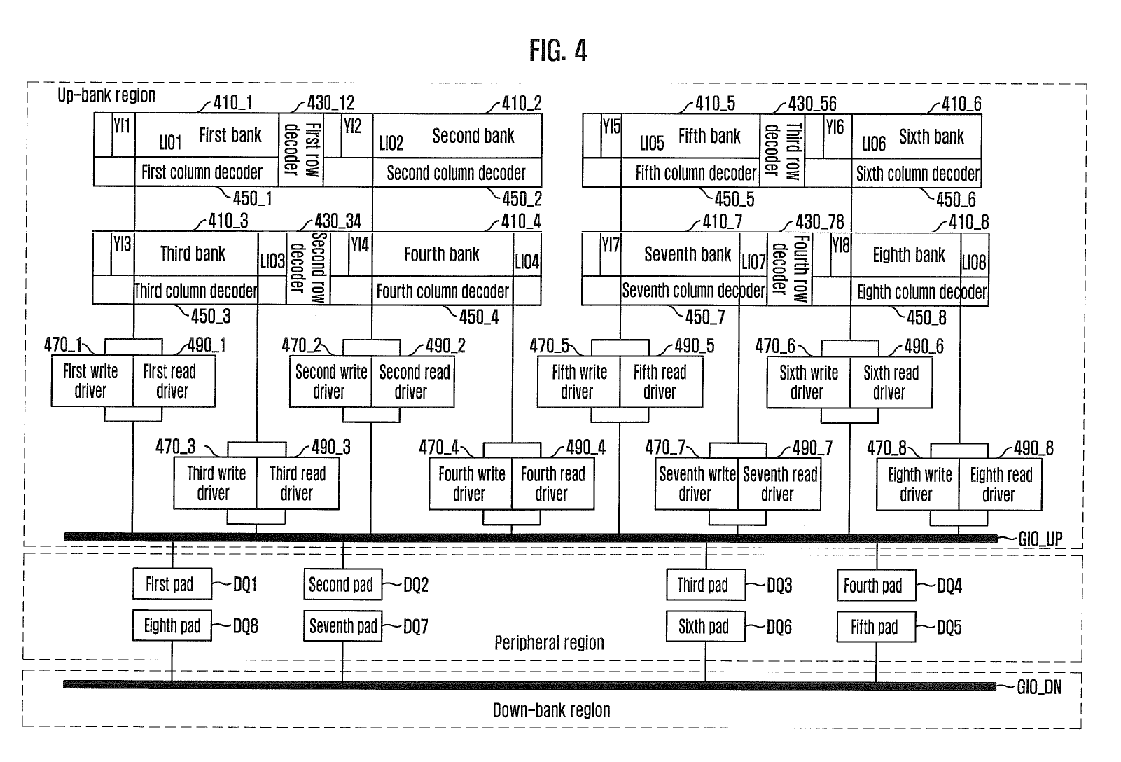

FIG. 4 is a block diagram illustrating a part of a semiconductor memory device in accordance with an embodiment of the present invention. FIG. 4 illustrates an up-bank region and a peripheral region for convenience. Since a down-bank region has the similar structure of the up-bank region, detail description thereof is omitted.

Referring to FIG. 4, the up-bank region includes first to eighth banks 410_1 to 410_8, first to fourth row decoders 430_12, 430_34, 430_56, and 430_78, first to eighth column decoders 450_1 to 450_8, and first to eighth write derivers 470_1 to 470_8, and first to eighth read drivers 490_1 to 490_8. The peripheral region includes first to eighth pads DQ1 to DQ8.

Each of the first to eighth banks 410_1 to 410_8 includes a plurality of memory cells for storing data. Each of the first to eighth banks 410_1 to 410_8 stores data in each of the memory cells in a write operation of a semiconductor memory device and outputs data stored in each of the memory cells in a read operation. The first to eighth banks 410_1 to 410_8 may be modified in the number and the structure thereof according to a design. Correspondingly, a designed circuit may also be changed.

Each of the first to fourth row decoders 430_12, 430_34, 430_56, and 430_78 selects one of word lines (not shown) by decoding a row address from an external device. Each of the first to eighth column decoders 450_1 to 450_8 activates one of first to eighth column selection signals YI1 to YI8 by decoding a column address from an external device.

Each of the first to eighth write drivers 470_1 to 470_8 transfers data, which is applied from an external device in a write operation of a semiconductor memory device, from an up global input/output line GIO_UP to a corresponding local input/output line. One or more of the first to eighth write drivers 470_1 to 470_8 may be included in a corresponding bank.

Each of the first to eighth read drivers 490_1 to 490_8 transfers data, which is stored in a corresponding bank in a read operation of a semiconductor memory device, from a corresponding local input/output line to an up global input/output line GIO_UP. One or more of the first to eighth read drivers 490_1 to 490_8 may be included in a corresponding bank.

Each of the first to eighth write drivers 470_1 to 470_8 and the first to eighth read drivers 490_1 to 490_8 controls data exchange between the first to eighth local input/output lines LIO1 to LIO8 and the up global input/output line GIO_UP. Each of the first to eighth writer drivers with a corresponding read driver may be referred as a data exchanger, hereinafter.

For example, the first write driver 470_1 and the first read driver 490_1 are referred as a first data exchanger, and the second write driver 470_2 and the second read driver 490_2 are referred as a second data exchanger. The third write driver 470_3 and the third read driver 490_3 are referred as a third data exchanger, and the fourth write driver 470_4 and the fourth read driver 490_4 are referred as a fourth data exchanger. the fifth write driver 470_5 and the fifth read driver 490_5 are referred as a fifth data exchanger, and the sixth write driver 470_6 and the sixth read driver 490_6 are referred as a sixth data exchanger. The seventh write driver 470_7 and the seventh read driver 490_7 are referred as a seventh data exchanger, and the eighth write driver 470_8 and the eighth read driver 490_8 are referred as an eighth data exchanger.

In the present embodiment, areas and lengths of the GIO are minimized by arranging the data exchangers between corresponding banks and the global input/output line. Hereinafter, arrangement of each constituent element according to the present embodiment will be described.

The first to eighth banks 410_1 to 410_8 may be arranged in a first direction and a second direction. Here, the first direction may be a vertical direction, that is, a column direction. The second direction is a direction crossing the first direction, that is, a row direction. In other word, the first bank 410_1 and the third bank 410_3 are stacked and arranged in a column direction, and the second bank 410_2 and the fourth bank 410_4 are stacked and arranged in a column direction. The fifth bank 410_5 and the seventh bank 410_7 are stacked and arranged in a column direction, and the sixth bank 410_6 and the eighth bank 410_8 are stacked and arranged in a column direction.

Then, the first to eighth data exchangers corresponding to the first to eighth banks 410_1 to 410_8 may be connected to the first to eighth local input/output lines LIO1 to LIO8 for transferring data inputted to or outputted from a corresponding bank. Each of the first to eighth local input/output lines LIO1 to LIIO8 may be formed of a positive local input/output line and a negative local input/output line. For convenience, the positive local input/output line and the negative local input/output line are shown as one local input/output line.

Here, a first metal line denotes a metal line where the first to eighth local input/output lines LIO1 to LIO8 are formed, and a second metal line denotes a metal line where the first to eighth column selection signals YI1 to YI8 are transferred. It is preferable to form the first metal line as an upper metal line above the second metal line. It is because it may reduce coupling effect of data transferred to each local input/output line and each column selection signal.

Meanwhile, each of the first to eighth data exchangers is connected to the up global input/output line GIO_UP for inputting and outputting data corresponding to each of the first to fourth pads DQ1 to DQ4. The up global input/output line GIO_UP may be disposed in a row direction. The first to eighth data exchanger may be disposed between the first bank 410_3/fourth bank 410_4 and the up global input/output line GIO_UP and between the seventh bank 410_7/eighth bank 410_8 and the up global input/output line GIO_UP.

According to the present embodiment, a plurality of the first local input/output lines LIO1, a plurality of second local input/output lines LIO2, a plurality of fifth local input/output lines LIO5, and a plurality of sixth local input/output lines LIO6 corresponding to the first, second, fifth and sixth banks 410_1, 410_2, 410_5, and 410_6 are arranged to cross the third, fourth, seventh, and eighth banks 410_3, 410_4, 410_7, and 410_8, which are stacked.

For convenience, the first, second, fifth, and sixth banks 410_1, 410_2, 410_5, and 410_6, which are arranged in a row direction, are referred as a first up-bank array. The third, fourth, seventh, and eighth banks 410_3, 410_4, 410_7, and 410_8, which are arranged in a column direction and stacked with the first up-bank array, are referred as a second up-bank array.

According to the present embodiment, a plurality of first local input/output line LIO1, a plurality of second local input/output lines LIO2, a plurality of fifth local input/output lines LIO5, and a plurality of sixth local input/output lines LIO6 corresponding to the first up-bank array cross the second up-bank array.

For convenience, the first to fourth pads DQ1 to DQ4 are referred as an ‘up-pad’, and the fifth to eighth pads DQ5 to DQ8 is referred as a ‘down-pad’. The first up-bank array and the second up-bank array included in an up-bank region are referred as an ‘up-bank group’. A first down-bank array (not shown) and a second down-bank array (not shown), which are included in a down-bank region, are referred as a ‘down-bank group’.

The first to eighth data exchangers corresponding the up-bank group are referred as an up-data exchanger, and the first to eighth data exchangers (not shown) corresponding to the down-bank group are referred as a down-data exchanger.

According to the present embodiment, up-pads may be disposed to interface with the up-data exchanger based on data on the up global input/output line GIO_UP, and down-pads may be disposed to interface with the down-data exchangers based on data on the down global input/output line GIO_DN.

Finally, data corresponding to the up-bank group may be inputted or outputted through the up-pad and the up global input/output line GIO_UP, and data corresponding to a down-bank group may be inputted or outputted through the down-pad and the down global input/output line GIO_DN. In this case, the down-bank group must include eight banks having addresses corresponding to the first to eighth banks 410_1 to 410_8 in the up-bank group. That is, it is preferable to design one bank to include into an up-bank group and a down-bank group. For example, when the first bank 410_1 is accessed, data corresponding to the first bank 410_1 can be input and output through the up-pad and the down-pad. The number of banks and dividing the banks can vary according to the design thereof.

Meanwhile, the up-pads may be disposed above an up-bank region. In this case, an up-data exchanger corresponding to the up-bank group may be disposed between the up-pad and the first up-bank array, and an up global input/output line GIO_UP may be disposed between the up-pad and the up-data exchanger. That is, the up-pad may be disposed to interface with the up-data exchanger based on data on the up global input/output line GIO_UP. Then, it is preferable that a plurality of third local input/output lines LIO3, a plurality of fourth local input/output lines LIO4, a plurality of seventh local input/output lines LIO7, and a plurality of eighth local input/output lines LIO8 corresponding to the second up-bank array are disposed to cross the first up-bank array.

The down-pads may be disposed below the down-bank region. Since related other circuits are arranged similar to the arrangement of circuits that was changed by disposing the up-pad above the up-bank region, detail description thereof is omitted.

Hereinafter, a write operation and a read operation of a semiconductor memory device according to an embodiment of the present invention will be described. For convenience, the write and read operations will be described based on a case of accessing the first bank 410_1. Also, a process of accessing a corresponding bank by decoding a column address and a row address is omitted.

In a write operation, data corresponding to the first bank 401_1, which is designed to be divided into an up-bank group and a down-bank group, is applied through the first to eighth pads DQ1 to DQ8, and the data is transferred to a plurality of data exchangers through the up global input/output line GIO_UP and the down global input/output line GIO_DN. The data inputted through the first to fourth pad DQ1 to DQ4 is inputted to a plurality of first write drivers 470_1. The output signal from the first write driver 470_1 may be stored in the first bank 410_1 through a plurality of first local input/output lines LIO1. Since a write operation in the down-bank region is similar to the write operation in the up-bank region, detail description thereof is omitted.

In a read operation, data stored in the first bank 410_1 is inputted to a plurality of first read drivers 490_1 through a plurality of first local input/output lines LIO1, and a signal outputted from a plurality of first read drivers 490_1 may be outputted through the up global input/output line GIO_UP corresponding to the first to fourth pads DQ1 to DQ4. Since a read operation in a down-bank region is similar to that in the up-bank region, the detail description thereof is omitted.

Here, the number of the up global input/output lines GIO_UP is reduced compared to that of the related art. That is, it means that the area and the length of the up global input/output lines GIO_UP are reduced too. In the present embodiment, it is possible to reduce a size of the semiconductor memory device by reducing the area and the length of the up global input/output lines GIO_UP. If the area and the length of the up global input/output lines GIO_UP are reduced, loading of the up global input/output lines GIO_UP becomes smaller compared to that of the related art. Therefore, a data transfer rate of input/output data increases thereby.

For example, since data corresponding to the first bank 410_1 and data corresponding to the third bank 410_3 are transferred through one up global input/output line GIO_UP, the data transfer rates corresponding to two banks are almost identical. It may be identically applied on the down global input/output lines GIO_DN. That is, the data transfer rate for all banks may be identical. Since data can be regularly received at a predetermined time from an external device, it is possible to improve the reliability of the semiconductor memory device.

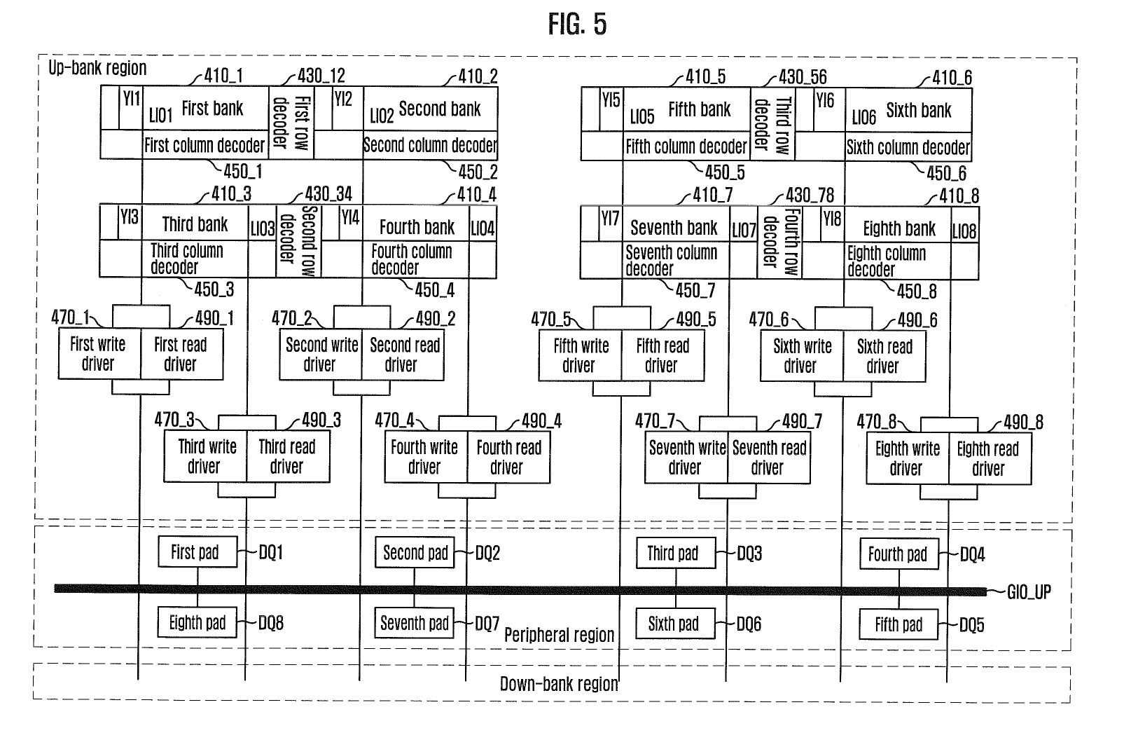

FIG. 5 is a block diagram illustrating a semiconductor memory device in accordance with another embodiment of the present invention. Unlike FIG. 4, arrangement of up global input/output lines GIO_UP and down global input/output lines GIO_DN in the semiconductor memory device of FIG. 5 is different from that in FIG. 4.

Referring to FIG. 5, the global input/output line GIO may be disposed between an up-pad such as first to fourth pads DQ1 to DQ4 and a down-pad such as fifth to eighth pads DQ5 to DQ8. In this case, a plurality of banks in an up-bank group and a plurality of banks included in a down-bank group may be designed to be accessed through other addresses. Therefore, if one bank is accessed, corresponding data can be outputted to the first to eighth pads DQ1 to DQ8.

Hereinafter, a write operation and a read operation of a semiconductor memory device according to an embodiment of the present invention will be described. For convenience, like reference numerals designate like elements throughout FIGS. 4 and 5. Therefore, detail description of the same element is omitted. Also, the write operation and the read operation will be described based on a case of accessing a first bank 410_1 as an example. Therefore, a process of accessing a corresponding bank by decoding a column address and a row address is omitted.

In a write operation, data corresponding to the first bank 410_1 is applied through the first to eighth pads DQ1 to DQ8, and the data is inputted to a plurality of first write drivers 470_1 through the global input/output lines GIO. A signal outputted from a plurality of first write drivers 470_1 may be stored in the first bank 410_1 through a plurality of first local input/output lines LIO1. The same write operation can be performed for banks included in the up-bank region. Also, the same write operation can be performed for banks included in the down-bank region.

In a read operation, data stored in the first bank 410_1 is inputted to a plurality of first read drivers 490_1 through a plurality of first local input/output lines LIO1, and a signal outputted from a plurality of first read drivers 490_1 may be outputted through global input/output line GIO corresponding to the first to eighth pads DQ1 to DQ8. The same read operation is performed for each of banks in the up-bank region, and the same read operation is performed for each of banks in the down-bank region.

Although FIG. 5 shows a plurality of banks in the up-bank group and the down-bank group which can be access through different addresses, one bank of FIG. 5 can be designed to be included in the up-bank group and the down-bank group like that of FIG. 4. That is, a global input/output line of FIG. 5 can be designed as an up global input/output line corresponding to an up-bank group and a down global input/output line corresponding to a down-bank group. In this case, the write operation and the read operation of a semiconductor memory device are identical to those of FIG. 4. Therefore, detail description thereof is omitted

As described above, the semiconductor memory device according to the present embodiment include the less number of global input/output lines compared to that of the related art. That is, the area and the length of the global input/output line are reduced. Therefore, the loading of the global input/output line decreases and the data transfer rate for input/output data increases.

For example, due to the same global input/output line, a data transfer rate of data corresponding to the first bank 410_1 may be identical to the data transfer rate corresponding to the third bank 410_3. That is, the data transfer rates for all banks are the same. Therefore, the reliability of the semiconductor memory device can be improved because data can be regularly received at a predetermined time from an external device.

Embodiments of the present invention relate to a semiconductor memory device that stably transfers data at a high speed and has a relatively small circuit area by effectively arranging data input/output lines that are connected to a plurality of stacked banks. It is also possible to increase the data transfer rate by reducing the loading of the global input/output line. Furthermore, it is possible to improve the reliability of the semiconductor memory device by optimizing the data transfer rate corresponding to each of the banks.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device, comprising:
a first plurality of banks arranged in a first direction to form a first group of banks;
a second plurality of banks arranged in the first direction to form a second group of banks, the first group of banks and the second group of banks arranged in a second direction;
a first local data line arranged in the second direction to cross a bank of the second plurality of banks and to transfer input/output data to a bank of the first plurality of banks;
a second local data line arranged in the second direction to transfer input/output data to the bank of the second plurality of banks;
a global data line disposed in the first direction that crosses the second direction; and
a data exchanger disposed between the second plurality of banks and the global data line configured to control data exchange between the first and second local data lines and the global data line.

2. The semiconductor memory device of claim 1, further comprising:
a row decoder configured to select a word line corresponding to at least one bank within the first or second pluralities of banks by decoding an input row address; and
a column decoder configured to activate a selection signal corresponding to one bank among the first and second pluralities of banks by decoding an input column address.

3. The semiconductor memory device of claim 1, wherein the data exchanger includes:
a first data exchanger, the first data exchanger controlling data exchange between the first local data line and the global data line; and
a second data exchanger, the second data exchanger controlling data exchange between the second local data line and the global data line.

4. The semiconductor memory device of claim 3 wherein:
the first data exchanger includes a first write driver configured to drive the first local data line according to data applied on the global data line, and a first read driver configured to drive the global data line according to the data applied on the first local data line; and
the second data exchanger includes a second write driver configured to drive the second local data line according to the data applied on the global data line, and a second read driver configured to drive the global data line according to the data applied on the second local data line.

5. The semiconductor memory device of claim 2, wherein:
the first local data line comprises a first metal line and a first upper metal line, the first upper metal line is formed between the first plurality of banks and the first data exchanger, and the first metal line is formed between the first data exchanger and the global data line for transferring the selection signal to the first data exchanger, and
the second local data line comprises a second metal line and a second upper metal line, the second upper metal line is formed between the second plurality of banks and the second data exchanger, and the second metal line is formed between the second data exchanger and the global data line for transferring the selection signal to the second data exchanger.

6. A semiconductor memory device, comprising:
a first plurality of banks arranged in a first direction to form a first up-bank array;
a second plurality of banks arranged in the first direction to form a second up-bank array, the first up-bank array and the second up-bank array arranged in a second direction that crosses the first direction;
a plurality of first local data lines arranged to cross the second up-bank array for transferring input/output data to/from the first up-bank array;
a plurality of second local data lines configured to transfer input/output data to/from the second up-bank array;
a plurality of data exchangers configured to control data exchange between the plurality of first local data lines and the plurality of second local data lines, and the global data line, and disposed between the global data line arranged in the second direction and the plurality of banks; and
a plurality of pads coupled to the global data line and disposed to interface with the data exchangers based on data on the global data line.

7. The semiconductor memory device of claim 6, wherein the plurality of pads receive and output data corresponding to data in the plurality of banks.

8. The semiconductor memory device of claim 6, further comprising:
a row decoder configured to select a word line corresponding to at least one bank within the first or second up-bank arrays by decoding an input row address; and
a column decoder configured to activate a selection signal corresponding to one bank among the first and second up-bank arrays by decoding an input column address.

9. The semiconductor memory device of claim 6, wherein the plurality of data exchangers includes:
a plurality of first data exchangers, each data exchanger among the plurality of first data exchangers connected to a corresponding first local data line among the plurality of first local data lines, to control data exchange between the corresponding first local data line and the global data line; and
a plurality of second data exchangers, each data exchanger among the plurality of second data exchangers connected to a corresponding second local data line among the plurality of second local data lines, to control data exchange between the corresponding second local data line and the global data line.

10. The semiconductor memory device of claim 9, wherein:
the first data exchanger includes a first write driver configured to drive the first local data line according to data applied on the global data line, and a first read driver configured to drive the global data line according to the data applied on the first local data line; and
the second data exchanger includes a second write driver configured to drive the second local data line according to the data applied on the global data line, and a second read driver configured to drive the global data line according to the data applied on the second local data line.

11. The semiconductor memory device of claim 8, wherein:
the first local data line comprises a first metal line and a first upper metal line, the first upper metal line is formed between the first plurality of banks and the first data exchanger, and the first metal line is formed between the first data exchanger and the global data line for transferring the selection signal to the first data exchanger, and
the second local data line comprises a second metal line and a second upper metal line, the second upper metal line is formed between the second plurality of banks and the second data exchanger, and the second metal line is formed between the second data exchanger and the global data line for transferring the selection signal to the second data exchanger.
